(19) United States
(12) Patent Application Publication
(10) Pub. No.: US 2016/0104601 A1
(43) Pub. Date: Apr. 14, 2016

(54) LOCAL DRY ETCHING APPARATUS

(71) Applicant: SPEEDFAM Co., Ltd., Ayase-city (JP)

(72) Inventor: Yasushi OBARA, Tokyo (JP)

(73) Assignee: SPEEDFAM Co., Ltd., Ayase-city (JP)

(21) Appl. No.: 14/876,573

(22) Filed: Oct. 6, 2015

(30) Foreign Application Priority Data
Oct. 10, 2014 (JP) 2014-208630

(51) Int. Cl. H01J 37/32

(52) U.S. Cl. CPC H01J 37/3244; H01J 37/32009; H01J 37/32715

(57) ABSTRACT

A local dry etching apparatus includes a single vacuum chamber, a plurality of gas introduction units each including a discharge tube having an injection port opened in the vacuum chamber, a single workpiece table disposed in the vacuum chamber and mounting a workpiece thereon, a table driving device, a table driving control device, a gas supply device for supplying raw material gases to the gas introduction units, a single electromagnetic wave oscillator, plasma generation portions each formed to each of the discharge tubes of the gas introduction units, and an electromagnetic wave transmission unit having an electromagnetic wave switching unit capable of switching an electromagnetic wave such that one of the plasma generation portions is irradiated with the electromagnetic wave, in which the respective gas introduction units inject plasma having different fabrication characteristics.

### CROSS-REFERENCE TO RELATED APPLICATIONS

The disclosure of Japanese Patent Application No. 2014-208630 filed on Oct. 10, 2014 including the specification, drawings, and abstract is incorporated herein by reference in its entirety.

### BACKGROUND OF THE INVENTION

1. Field of the Invention

The present invention relates to a local etching apparatus of locally fabricating the surface of a workpiece (material to be fabricated) such as a silicon wafer or a semiconductor wafer by dry etching.

2. Description of the Related Art

FIG. 1 is an explanatory view for explaining the principle of a method of flattening a workpiece by local dry etching using plasma. An active species gas G in plasma generated by a plasma generation portion A that constitutes a portion of a discharge tube B is injected from a nozzle N to the surface of a workpiece W. The workpiece W is mounted and fixed on a workpiece table T, and the workpiece table T is scanned at a speed and a pitch controlled in a horizontal direction relative to the nozzle N.

The workpiece W varies in thickness depending on a position and has fine unevenness before flattening fabrication. Before dry etching for flattening, the thickness in each of sectioned areas of the workpiece W is measured. This measurement provides data of the thickness at a position in each area, that is, position-thickness data.

In the local dry etching fabrication, the amount of a material to be removed in each area corresponds to a time during which the area is exposed to the active species gas G. Therefore, a relative speed of the nozzle passing by the workpiece (hereinafter, referred to as “nozzle speed”) is determined such that the nozzle moves at a low speed over a relatively thick portion (hereinafter, referred to as a relatively thick portion) Wa and at a high speed over a relatively thin portion.

FIG. 2 is a graph showing a distribution of an amount (depth) of a workpiece material to be removed per unit time with an injected active species gas, that is, an etching rate. This curve called etching rate profile is very similar to a Gaussian distribution curve. As shown in FIG. 2, the etching rate E has a maximum value Emax at the center line of the nozzle N and decreases as the distance increases from the center in the direction of radius r. Usually, a characteristic of the nozzle is represented in terms of a width having the etching rate E of a value one-half of Emax, that is, a half-value width d.

Thus, since the material removing capability shows a distribution according to the distance from the center of the nozzle, the amount of the material necessary to be removed from one area cannot be determined by consideration only for the nozzle speed over one area. That is, even though the material has been removed in one area, when a neighborhood area such as an adjacent area or an area further adjacent to the adjacent area is to be etched, the material is removed in an overlapped manner in accordance with the etching rate profile.

When a workpiece is fabricated by local etching fabrication and in a case where it is necessary to apply a plurality of fabrication processes under different conditions on one workpiece, this is coped with by using a plurality of apparatus corresponding to respective necessary fabrication characteristics or by exchanging nozzles in accordance with fabrication characteristics in a single apparatus in order to correspond to the plurality of fabrication characteristics (etching rate, etching profile, etching area, object material to be etched, etc.) (JP-A No. 2004-128079).

In contrast, for removing nanotopography which is a periodical fine unevenness, JP-A No. 2004-134661 discloses a technique of forming a main nozzle and an auxiliary nozzle to respective discharge tubes in a single vacuum chamber.

### SUMMARY OF THE INVENTION

When a plurality of apparatus are used as in JP-A No. 2004-128079, cost will be increased by so much as the number of vacuum chambers and peripheral equipment of the vacuum chambers (electromagnetic wave oscillators, gas supply devices, etc.), as well as the area for installing the apparatus will be increased, various components of the apparatus requiring control and adjustment will have to be used, and scheduling between the apparatus will become troublesome and complicate.

Further, since a fabrication period of time decided by fabrication conditions is necessary for every apparatus or every vacuum chamber, if the fabrication period of time for once is different for every apparatus or vacuum chamber, some apparatus or vacuum chambers have to stand-by and each of apparatus or vacuum chambers cannot be used without stand-by time, and a throughput cannot be improved efficiently.

Further, in a case where a workpiece is transported between the apparatus or vacuum chambers, since transfer arms are brought into contact with the workpiece by the number of transportation, this may increase the possibility of depositing particles and causing scratches on the workpiece.

Further, when nozzles are exchanged in a single vacuum chamber, the vacuum of the chamber should be broken upon the exchange of the nozzles. Upon the exchange, particles tend to be generated and carried on and a number of steps, for example, the inside of the vacuum chamber should be evacuated again to obtain vacuum conditions necessary for fabrication, thereby causing problems.

JP-A No. 2004-134661 only conceptionally discloses provision of a plurality of nozzles, but it neither discloses nor suggests specific constituent factors of the apparatus, particularly, electromagnetic wave supply system, plasma generation system, and apparatus operation system when the nozzles are provided to respective discharge tubes.

Thus, while there are technical disclosures of applying a plurality of the fabrication processes to the surface of the workpiece such as a silicon wafer, the subjects described above have not yet been addressed.

Recently, the dimension of semiconductor devices has been reduced remarkably year by year and the International Technology Roadmap for Semiconductors shows an aimed value of 19 nm for the interconnect width of a device by the year of 2018. In accordance with the size reduction of the interconnect width of the device, higher accuracy has been demanded for the flatness of the workpiece surface.

In the fabrication of scanning the entire surface of the workpiece as in the patent literatures described above, the flatness is improved for a certain range. However, if a portion where the flatness is locally poor (non-periodical poor portion) but cannot be removed only by the entire fabrication, such a portion cannot be amended because the portion has been left after fabrication along X-Y scanning.

In a case where flatness is locally poor, particularly, a portion where the slope of the unevenness shape is remarkable as illustrated, for example, in FIG. 3 (portion where the unevenness shape changes steeply, hereinafter referred to as “steeply changing portion”) is present at the surface of the workpiece, since the flatness of the entire workpiece is enhanced by improving the steeply changing portion, it is necessary to modify the steeply changing portion to a more moderate shape. However, since the etching amount is decreased under the fabrication conditions corresponding to the steeply changing portion, the productivity is worsened extremely.

Accordingly, it is also a subject required to be addressed in the future to efficiently improve the portion to be fabricated at a high throughput by a single apparatus or vacuum chamber, while enhancing the flatness of the workpiece, thereby obtaining a workpiece of high flatness and accuracy.

Further, materials of workpieces as the object of fabrication have become versatile in recent years and there are workpieces including a plurality of materials. When such workpieces are fabricated, apparatus having recipes adaptable to every different material are required by the number of the different materials, etc. and the subjects described above have not yet been addressed.

In order to solve the subjects described above, the present invention has a subject of providing a local dry etching apparatus having a plurality of fabrication characteristics while suppressing increase in the number of parts and the installation area for the apparatus in the local dry etching.

The subjects described above can be solved by the following techniques.

That is, the present invention provides, in a first aspect, a local dry etching apparatus of locally fabricating the surface of a workpiece by dry etching, including

a single vacuum chamber,

a plurality of gas introduction units each including a discharge tube having an injection port opened in the vacuum chamber,

a single workpiece table disposed in the vacuum chamber for mounting a workpiece,

a table driving device for driving the workpiece table,

a table driving control device for controlling the table driving device,

a gas supply device for supplying a raw material gas to the gas introduction units,

a single electromagnetic wave oscillator,

plasma generation portions each formed to each of the discharge tubes of the gas introduction units,

an electromagnetic wave transmission unit having an electromagnetic wave switching unit capable of switching an electromagnetic wave such that one of the plasma generation portions is irradiated with the electromagnetic wave generated by the single electromagnetic wave oscillator, and

the respective gas introduction units have different fabrication characteristics.

The present invention provides, in a second aspect, the local dry etching apparatus according to the first aspect, wherein a distance between each of the injection ports and the workpiece is made different, such that the respective gas introduction units have different fabrication characteristics.

The present invention provides, in a third aspect, the local dry etching apparatus according to the first aspect, wherein exhaustion units having different exhaustion conditions are located at the periphery of the injection ports, whereby the respective gas introduction units have different fabrication characteristics.

The present invention provides, in a fourth aspect, the local dry etching apparatus according to the third aspect, wherein the exhaustion units each include an exhaustion duct located at the periphery of the injection port and an exhaustion mechanism connected to the exhaustion duct, and at least one of the width of the exhaustion duct in the direction perpendicular to the axis of the discharge tube and the height of the exhaustion duct in the direction identical with the axis of the discharge tube is made different for every injection port, whereby the respective gas introduction units have different fabrication characteristics.

The present invention provides, in a fifth aspect, the local dry etching apparatus according to the third aspect, wherein the exhaustion units each include an exhaustion duct located at the periphery of the injection port and an exhaustion mechanism connected to the exhaustion duct, and an exhaustion amount of a reaction product gas formed upon dry etching fabrication by the exhaustion mechanism is made different for every injection port, whereby the respective gas introduction units have different fabrication characteristics.

The present invention provides, in a sixth aspect, the local dry etching apparatus according to the first aspect, wherein the diameter or the shape of each of the injection ports is made different, whereby the respective gas introduction units have different fabrication characteristics.

The present invention provide, in a seventh aspect, the local dry etching apparatus according to the first aspect, wherein a distance from each of the plasma generation portions to the surface of the workpiece mounted on the workpiece table is made different, whereby the respective gas introduction units have different fabrication characteristics.

The present invention provides, in an eighth aspect, the local dry etching apparatus according to the first aspect, wherein different kinds of gases are supplied into the discharge tubes, whereby the respective gas introduction units have different fabrication characteristics.

The present invention provides, in a ninth aspect, the local dry etching apparatus according to the first aspect, wherein an inert gas and/or a non-active raw material gas supplied to the gas introduction unit is supplied to the workpiece fabrication area and/or the periphery of the exhaustion duct.

The present invention provides, in a tenth aspect, the local dry etching apparatus according to the first aspect, wherein a temperature control unit is provided for heating and/or cooling at least a portion of the gas introduction units.

According to the present invention, since a plurality of discharge tubes each having an injection port are provided in the single vacuum chamber, and the fabrication characteristics of the injection ports of the discharge tubes are made different each other, local dry etching fabrication can be applied with various fabrication characteristics by entry of the workpiece for once without breaking the vacuum of the apparatus.

That is, a single local dry etching apparatus can be provided with a plurality of fabrication characteristics, a fabrication range can be widened and the throughput can be increased in the single local dry etching apparatus, and this also contributes to obtain a workpiece at high accuracy without contaminating the workpiece. Further, since the single electromagnetic wave oscillator is used in common with the plurality of the gas introduction units by using the electromagnetic wave switching unit, it is possible to attain simplified constitution and control of the apparatus and decrease the cost. Further, also a workpiece having a plurality of features, for example, including multiple materials and multiple characteristics of surface topographies can be processed by a single local dry etching apparatus.

### BRIEF DESCRIPTION OF THE DRAWINGS

FIG. 1 is an explanatory view for explaining the principle of a method of flattening a workpiece by local dry etching using plasma;

FIG. 2 is a graph showing the distribution of an etching rate of an injected active species gas;

FIG. 3 is a schematic view of a portion where the slope of an uneven shape at the surface of the workpiece is steep (a portion where the uneven shape changes steeply);

FIG. 4 is a fragmentary cross sectional view illustrating the outline of a local dry etching apparatus according to the present invention;

FIG. 5 is a plan view along line A-A in FIG. 4;

FIG. 6 is a fragmentary cross sectional view illustrating a first embodiment of a local dry etching apparatus according to the present invention;

FIG. 7 is a fragmentary cross sectional view illustrating a second embodiment of the local dry etching apparatus according to the present invention;

FIG. 8 is a fragmentary cross sectional view illustrating a third embodiment of the local dry etching apparatus according to the present invention;

FIG. 9 is a fragmentary cross sectional view illustrating a fourth embodiment of the local dry etching apparatus according to the present invention; and

FIG. 10 is a schematic view for a structure of pre-heating a gas introduction unit.

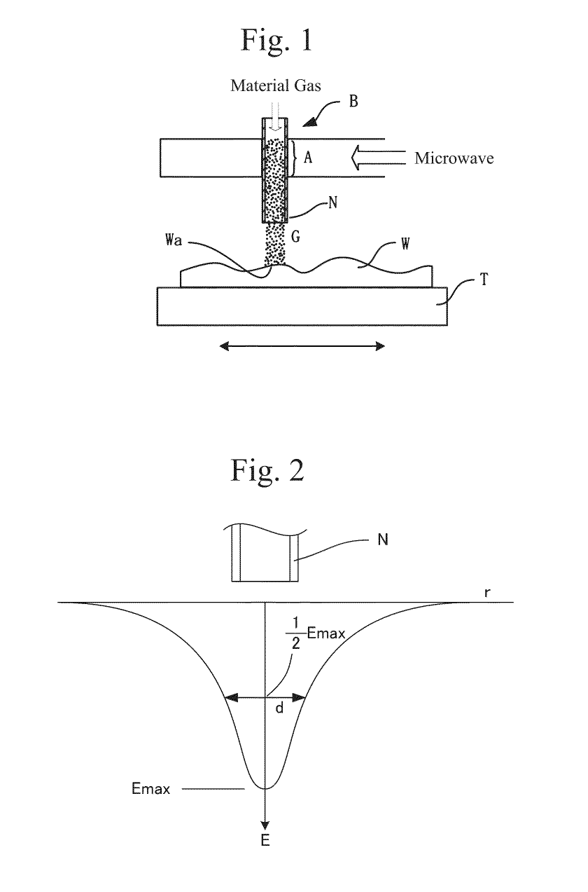

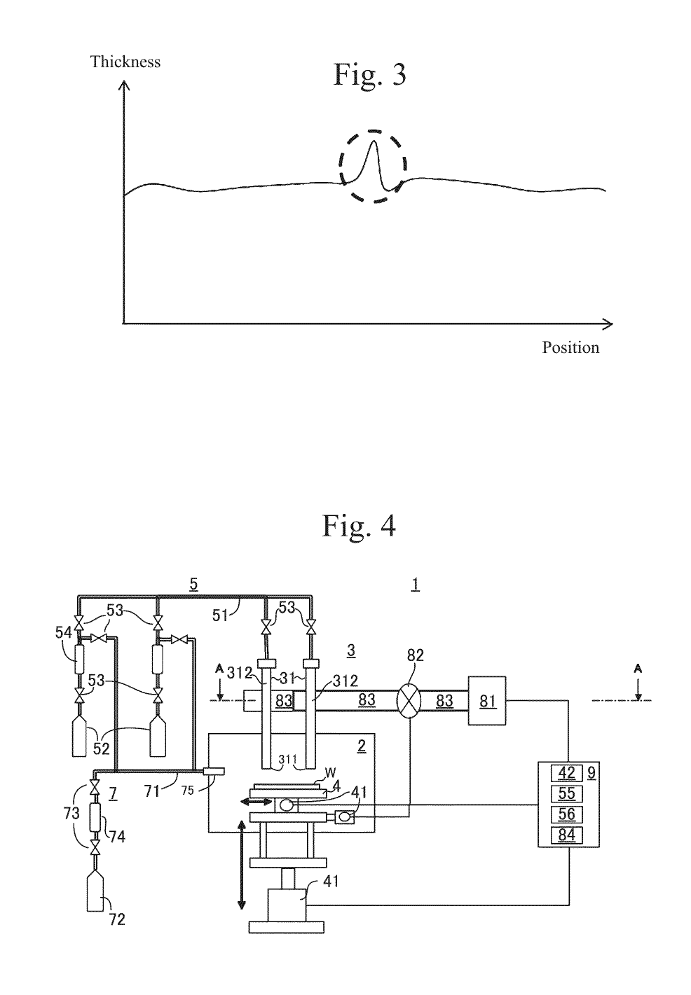

### DETAILED DESCRIPTION OF THE PREFERRED EMBODIMENTS

Preferred embodiments of the present invention are to be described below with reference to the drawings.

FIG. 4 is an explanatory view illustrating the outline of a preferred embodiment of a local dry etching apparatus of the present invention. A local dry etching apparatus 1 is an apparatus for locally fabricating the surface of a workpiece W by dry etching as has been described above. The local dry etching apparatus 1 as a preferred embodiment of the present invention has a single vacuum chamber 2, and injection ports 311 of the discharge tubes 31 are opened in the vacuum chamber 2. The discharge tube 31 and the injection port 311 of the discharge tube 31 constitute a gas introduction unit 3 and the gas introduction unit 3 is disposed in plurality. That is, the injection ports 311 of the discharge tubes 31 are opened in plurality in the vacuum chamber 2.

A single workpiece table 4 for mounting a workpiece W is disposed in the vacuum chamber 2. A table driving device 41 is provided for driving the workpiece table 4 in the directions of X, Y and Z as shown by arrows. A table driving control device 42 is provided outside of the vacuum chamber 2 for controlling the table driving device 41.

A raw material gas is supplied from a gas supply device 5 to each of the gas introduction units 3, that is, to each of the discharge tubes 31. A plasma generation portion 312 is provided to each of the discharge tubes 31 of the gas introduction units 3. An electromagnetic wave generated by a single electromagnetic wave oscillator 81 is introduced by way of an electromagnetic wave transmission unit 83 to the plasma generation portions 312 and the raw material gas passing by the inside of the discharge tube 31 of the gas introduction unit 3 is converted into a plasma by irradiation with the electromagnetic wave.

The electromagnetic wave transmission unit 83 has an electromagnetic wave switching unit 82 and the electromagnetic wave switching unit 82 can switch such that only one of the plasma generation portions 312 is irradiated with the electromagnetic wave. The electromagnetic wave switching unit 82 is controlled by an electromagnetic wave switching unit control device 84.

The gas supply device 5 includes a plurality of raw material gas reservoirs 52 filled with different kinds of raw material gases, for example, gases such as SF₆, NF₃, and CF₄, respectively, valves 53 for turning the supply of the raw material gases to on and off, mass flow controllers 54 for controlling flow rates, and a supply pipe 51 for connecting them and introducing the gases to the flow inlets of the discharge tubes 31. The valves 53 and the mass flow controllers 54 are controlled by a valve control device 55 and a mass flow controller control device 56. While the valves control device 55 are connected to the valve 53 and the mass flow controller control device 56 is connected to the mass flow controllers 54, they are not illustrated in the drawing.

An inert gas supply device 7 is provided in parallel with the gas supply device 5. The inert gas supply device 7 includes an inert gas reservoir 72 filled with an inert gas, for example, nitrogen, argon, or helium, inert gas valves 73 for turning the supply of the inert gas to on and off, an inert gas mass flow controller 74 for controlling the flow rate of the inert gas. The inert gas in the inert gas reservoir 72 is introduced by way of the inert gas valves 73, the inert gas mass flow controller 74, and the inert gas supply pipe 71 to an inert gas introduction port 75. The inert gas introduction port 75 is opened in the vacuum chamber 2.

The inert gas valves 73 and the inert gas mass flow controller 74 are controlled by the valve control device 55 and the mass flow controller control device 56 in the same manner as the valves 53 and the mass flow controller 54. The valve control device 55 and the mass flow controller control device 56 constitute, together with the table driving control device 42 and the electromagnetic wave switching unit control device 84, a component of the main control device 9. While the valve control device 55 is connected to the inert gas valve 73 and the mass flow controller control device 56 is connected to the inert gas mass flow controller 74, they are not illustrated in the drawing.

The gas supply device 5 and the inert gas supply device 7 are connected each other, and can send the raw material gas and the inert gas each alone or in admixture to one or both of the flow inlet of the discharge tubes 31 and the inert gas introduction port 75 by on-off operation of the valves 53 and the inert gas valves 73.

In the local dry etching fabrication of the workpiece according to the invention, thickness (uneven shape) in each of the areas sectioned for every workpiece is measured in the preceding stage. Based on the data for the thickness at the position of each of the areas, that is, position-thickness data obtained by the measurement, the fabrication characteristics are adjusted such that they are different for every gas introduction unit 3 (discharge tube 31 and injection port 311). In other words, fabrication recipes are prepared for every gas introduction unit 3. Local dry etching fabrication using a plurality of the gas introduction units 3 is to be illustrated below.

The position-thickness data of a workpiece is assumed to have been obtained already. First, the workpiece W is entered and mounted on the workpiece table 4 in the vacuum chamber 2 and the vacuum chamber 2 is evacuated. Alternatively, the workpiece W is entered and mounted from a transport chamber which is provided adjacent to the already evacuated vacuum chamber 2.

A raw material gas is supplied to the discharge tube 31 of the gas introduction unit 3 first selected from a plurality of the gas introduction units 3 each having the discharge tube 31 and the injection port 311. Concurrently, an electromagnetic wave is generated by the electromagnetic wave oscillator 81. The electromagnetic wave transmission unit 83 is previously switched such that the generated electromagnetic wave is transmitted to the plasma generation portion 312 of the selected discharge tube 31.

When the plasma generation portion 312 of the gas introduction unit 3 is irradiated with the electromagnetic wave, the raw material gas passing through the inside of the discharge tube 31 is converted into a plasma to form an active species gas. The thus formed active species gas proceeds to the injection port 311 of the gas introduction unit 3 and injected therefrom to the surface of the workpiece W. The injection port 311 is moved relatively so as to scan the surface of the workpiece W. The scanning speed when the gas passes each of the areas is controlled such that the surface of the workpiece is flattened in accordance with the unevenness shape. Thus, local dry etching fabrication is performed.

As the fabrication characteristic provided in this step, that is provided by the firstly selected gas introduction unit 3, a characteristic, for example, a somewhat broader etching profile is given. According to the fabrication characteristic with a broad etching profile, the entire surface can be flattened efficiently. A specific way of determining the fabrication characteristic of the etching profile is to be described with reference to the preferred embodiments to be described later.

After the completion of the first fabrication process, gas supply and electromagnetic wave oscillation are stopped and then the succeeding fabrication process is performed, for example, with an etching profile of a narrow fabrication characteristic by using the next gas introduction unit 3. For this purpose, valves 53 are switched such that the gas is supplied to the next gas introduction unit 3 and, concurrently, the electromagnetic wave switching unit 83 is switched such that the plasma generation portion 312 of the discharge tube 31 of the gas introduction unit 3 is irradiated with the electromagnetic wave from the electromagnetic wave oscillator 81.

Thus, a portion where the slope of the unevenness shape is large (portion where the unevenness shape changes steeply) on the surface of the workpiece, which is not removed completely in the preceding stage because of using an etching profile having the broad fabrication characteristic, can be flattened at high accuracy by a narrower etching profile in the succeeding stage.

Since a plurality of gas introduction units 3 can be provided with different fabrication characteristics, local dry etching fabrication can be performed with various fabrication characteristics by loading the workpiece only for once without breaking vacuum in the apparatus.

In other words, a single local dry etching apparatus can be provided with a plurality of fabrication characteristics in the invention, so that fabrication can be performed for a wider range and at a higher throughput in the single local dry etching apparatus, as well as this also contributes to the attainment of a workpiece at high accuracy without contamination of the workpiece. Further, since the single electromagnetic wave oscillator is used in common with a plurality of gas introduction units by using the electromagnetic wave switching unit, the constitution and the operation of the apparatus can be simplified and the cost can be decreased. Further, also a workpiece having a plurality of features, for example, including multiple materials and multiple characteristics of surface topographies can be fabricated by a single local dry etching apparatus.

The etching profile of the broad fabrication characteristic can be used optionally either in the first stage or in the latter stage with no restriction to the order of the stages.

Examples of methods of providing different fabrication characteristics to respective gas introduction units are to be described below.

### First Embodiment

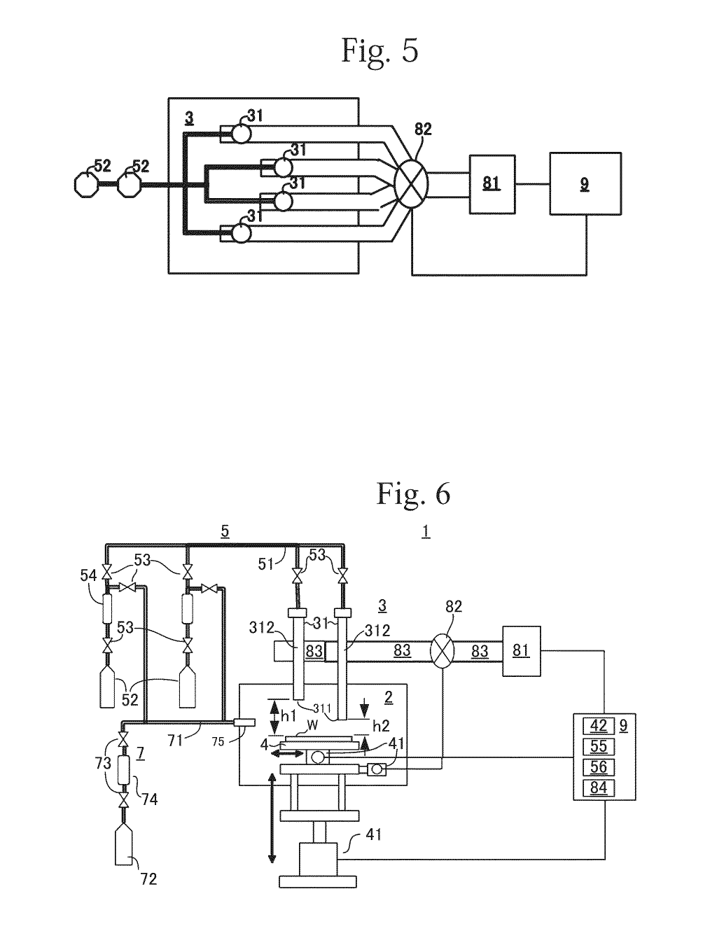

FIG. 6 is a fragmentary cross sectional view illustrating a first embodiment of the local dry etching apparatus 1 of the present invention. In this embodiment, for obtaining the different etching profiles (fabrication characteristics) described above, a distance between each of the injection ports 311 of the gas introduction units 3 and the surface of the workpiece is made different. Since the explanation for FIGS. 4 and 5 that have been described as the outline for the embodiments of the invention are identical with that for the present case, they are incorporated herein and only the different matters are to be described.

The injection ports 311 of the discharge tubes 31 in the gas introduction unit 3 are configured such that the distances h1 and h2 between the tip (lower end) of the injection ports 311 of the discharge tubes 31 in the gas introduction unit 3 and the surface of the workpiece are different for every discharge tube 31. In a case where the distance is longer, since the flow of the active species gas injected from the injection port 311 spreads gradually as it is away from the lower end of the injection port 311, the etching profile becomes broader. By utilizing the property, the distance is set longer as h1 in the first fabrication, whereas the distance is set shorter as h2 in the fabrication at the succeeding stage.

As described above, since the distance between the respective injection ports 311 and the workpiece W are made different, the fabrication characteristics of the plasma injected from the respective injection ports 311 can be made different.

### Second Embodiment

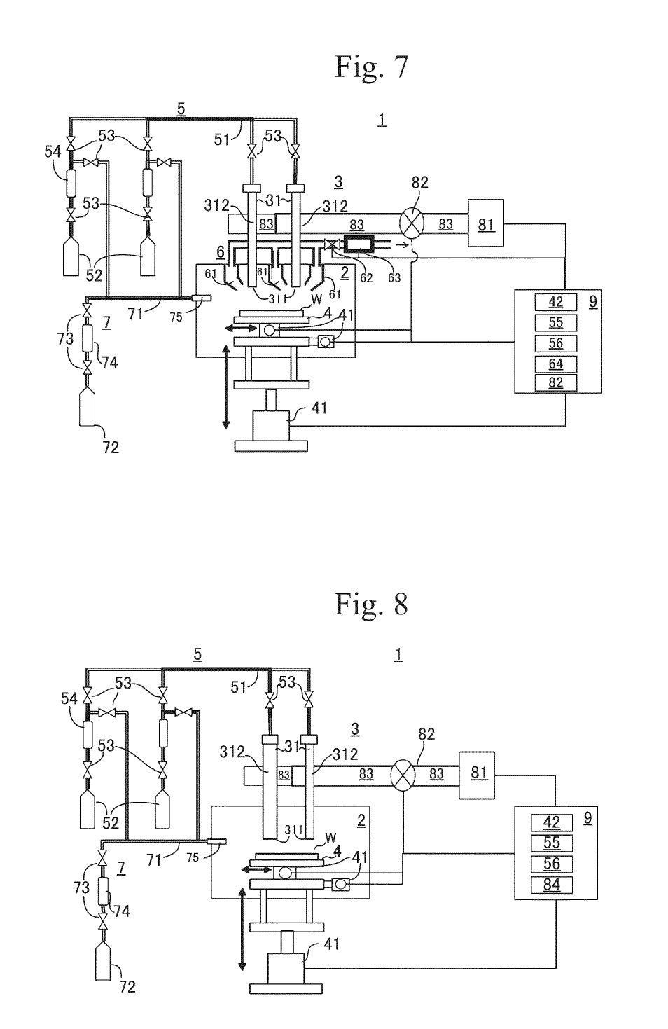

FIG. 7 is a fragmentary cross sectional view illustrating a second embodiment of the local dry etching apparatus 1 of the present invention. The local dry etching apparatus 1 of this embodiment includes an exhaustion unit 6 for exhausting a gas in the vacuum chamber 2 from the vicinity of a portion to be fabricated during etching operation.

In this embodiment, exhaustion units 6 having different exhaustion conditions are located at the periphery of the injection ports 311 and the sizes of the units are made different in the local dry etching apparatus 1, by which the fabrication characteristics of the plasma injected from the respective injection ports 311 can be made different.

The exhaustion unit 6 includes an exhaustion duct 61 located at the periphery of the injection port 311 and an exhaustion mechanism having an exhaustion valve 62 connected to the exhaustion duct 61 and an exhaustion pump 63. At least one of the width of the exhaustion duct 61 in a direction perpendicular to the axis of the discharge tube 31 and the height of the exhaustion duct 61 in the direction identical with the axis of the discharge tube 31 is made different for every injection port 311, by which the fabrication characteristics of the plasma injected from respective injection port 311 can be made different. Means for making the fabrication characteristics different can be attained by decreasing at least one of the width of the exhaust duct 61 in the direction perpendicular to the axis of the discharge tube 31 and the height of the exhaustion duct 61 in the direction identical with that of the axis of the discharge tube 31 in a case of setting the fabrication characteristic for a broader etching profile. In a case of setting the fabrication characteristic for a narrower etching profile, this can be attained by increasing at least one of the width of the exhaustion duct 61 in the direction perpendicular to the axis of the discharge tube 31 and the height of the exhaustion duct 61 in the direction identical with the axis of the discharge tube 31 when compared with the sizes, for example, the width and the height of the exhaustion duct 61 used in the fabrication characteristic for the broader etching profile.

Further, the etching profile can be changed also by changing the number of setting, position for locating the exhaustion ducts 61, etc. in addition to the change of the size such as the width and the height of the exhaustion duct 61.

It is also possible to arrange the exhaustion ducts 61 such that the axial direction of one or more exhaustion ducts 61 is in parallel with the axis of the injection port 311 of the gas introduction unit 3, or arrange such that the exhaustion duct 61 is coaxial with the injection port 311 of the gas introduction unit 3. In a case of coaxially or concentrically arranging the exhaustion duct 61, the exhaustion ducts 61 may be formed as multiple tubes.

Further, the exhaustion duct 61 may also be provided with a mechanism such as a movable unit that can optionally adjust the size, the number of setting, and the position for locating the exhaustion duct 61 in accordance with every result of fabrication or fabrication recipe of a workpiece W, in addition to predetermined size, number of setting, and position for locating the exhaustion duct 61.

Further, in a case where the exhaustion unit 6 includes the exhaustion duct 61 located at the periphery of the injection port 311, the exhaustion valve 62 and the exhaustion pump 63 connected to the exhaustion duct 61 in the same manner as described, the fabrication characteristic of the plasma injected from the respective injection ports 311 can be made different by making the exhaustion amount of the reaction product gas formed during etching with the exhaustion mechanism different for every injection port 311.

The exhaustion valve 62 and the exhaustion pump 63 are controlled by an exhaustion controller 64. The exhaustion controller 64 constitutes a component of a main control device 9, together with the mass flow controller control device 56, the table driving control device 42, and the electromagnetic wave switching unit control device 84.

When the exhaustion unit 6 is operated, since a gas at the periphery of the injection port 311 is sucked, the flow of the injected active species gas or the non-active gas already loosing the activity is changed and, in accordance therewith, the fabrication characteristic, that is, the etching profile can be broader or narrower.

That is, the etching profile can be changed by changing the number, the diameter of the opening, the position for locating or the exhaustion amount of the exhaustion duct 61.

### Third Embodiment

FIG. 8 is a fragmentary cross sectional view illustrating a third embodiment of the local dry etching apparatus 1 of the present invention. In the local dry etching apparatus 1 of this embodiment, the fabrication characteristics of the plasma injected from respective injection ports 311 are made different by varying the diameter of the injection ports 311 of the discharge tubes 31 that constitute the gas introduction units 3.

So long as other conditions are identical, a broader etching profile can be obtained in a case of using a injection port 311 having a larger diameter and a narrower etching profile can be obtained in a case of using a injection port 311 having a smaller diameter.

Further, the fabrication characteristics of the plasma injected from respective injection ports 311 can be made different by deforming the shape of at least one injection port 311 from a true circle to a flattened shape or the like.

### Fourth Embodiment

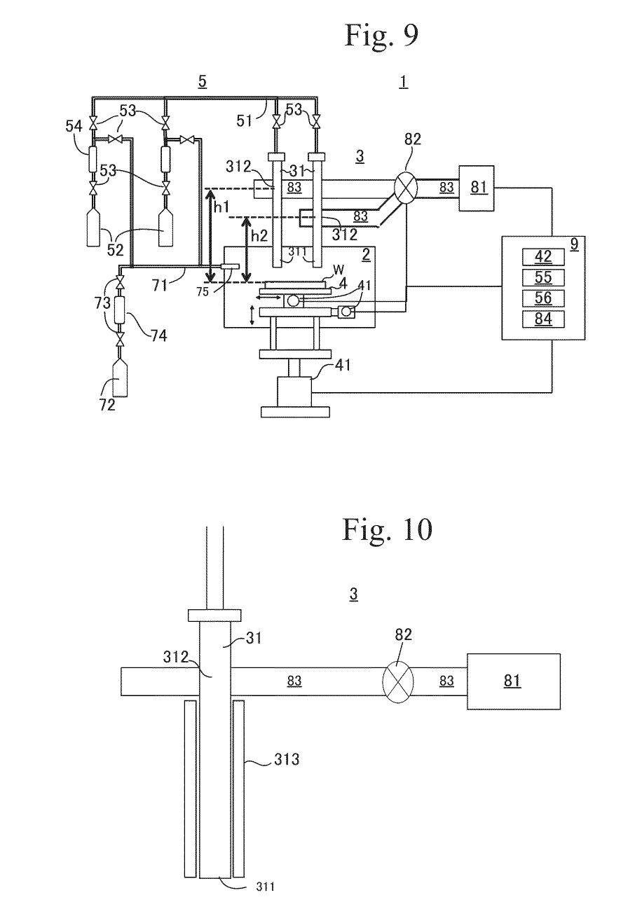

FIG. 9 is a fragmentary cross sectional view illustrating a fourth embodiment of the local dry etching apparatus 1 of the present invention. In the local dry etching apparatus 1 of this embodiment, the fabrication characteristics of a plasma injected from respective injection ports 311 can be made different by varying the distances from the plasma generation portions 312 to the surface of a workpiece W mounted on a workpiece table 4.

In the plasma generation portion 312, a raw material gas is converted into an active species gas in a plasma by irradiation with an electromagnetic wave. By the way, the active species gas loses its activity with lapse of time and, finally, restores to the original raw material gas. That is, this is an extremely unstable gas. Accordingly, as the distance along which the active species gas passes through the inside of the discharge tube 31 and reaches the surface of the workpiece W, that is, the distance from the plasma generation portion 312 to the surface of the workpiece W mounted on the workpiece table 4 is different, the etching profile becomes different while other conditions are identical. In this embodiment, the fabrication characteristic of each of the discharge tubes 31 is varied by making the distance different between the surface of the workpiece W and the plasma generation portion 312 for every discharge tube.

### Fifth Embodiment

Each of the local dry etching apparatus 1 in FIGS. 4 to 9 includes a plurality of raw material gas reservoirs 52 and an inert gas reservoir 72. In a fifth embodiment, in a case where the raw material gas reservoirs 52 is filled with raw material gases different from each other, the fabrication characteristics of the plasma injected from respective injection ports 311 are made different by selecting the kind of the raw material gas, selecting the inert gas, or using them in admixture by turning on and off the valves 53 and 73.

Different fabrication characteristics, i.e., different etching profiles can be obtained when the raw material gases are different, they are mixed or, further, an inert gas is mixed. As a matter of fact, when different raw material gases are used respectively, more complicate local dry etching fabrication can be attained, for example, by selectively etching to remove specified materials that constitute the workpiece by using a plurality of gas introduction units 3.

### Sixth Embodiment

In a sixth embodiment, at least one of the raw material gas and the inert gas can be sent from an inert gas introduction port 75 to a fabrication area or at the periphery of the exhaustion duct 61 in each of the examples described above. Thus, the raw material gas and/or the inert gas restrict diffusion of the active species gas, and restrict the flow flux of radicals of the active species gas by the pressure thereof and act in the direction of decreasing the etching profile, and the etching profile can be adjusted. That is, the atmosphere of the fabrication area can be changed by increasing/decreasing the amount of the raw material gas and/or the inert gas to be supplied, by which different fabrication characteristics, that is, different etching profiles can be attained.

By the way, it has been known that the temperature of the gas introduction unit 3 gives an effect on the fabrication characteristic of the local dry etching such as generation of the plasma or change of the etching rate. In each of the embodiments described above, when a temperature control unit is provided for heating and/or cooling at least a portion of the gas introduction unit 3, control for the local dry etching fabrication can be achieved at a higher accuracy.

In each of the embodiments described above, the gas introduction unit 3 has been explained with reference to the example of using two units but the number of the gas introduction units 3 is not restrictive but may be three or more.

In the present invention, since the fabrication process by a plurality of fabrication characteristics can be applied to a single workpiece by a single apparatus, it is possible to solve the subjects in a case of performing the fabrication process by a plurality of fabrication characteristics by a plurality of apparatus (increase of the cost, increase of the installation area of the apparatus, versatile control and adjustment of constituent components of the apparatus, troublesome and complicated scheduling between fabrication apparatus, causing of stand-by state of chambers due to difference between the fabrication period of time of the apparatus (lowering of throughput), deposition of particles, occurrence of contact flaws due to transportation of workpieces between the apparatus, etc.).

1. A local dry etching apparatus of locally fabricating the surface of a workpiece by dry etching, comprising;
a single vacuum chamber,
a plurality of gas introduction units each including a discharge tube having an injection port opened in the vacuum chamber,
a single workpiece table disposed in the vacuum chamber for mounting a workpiece,
a table driving device for driving the workpiece table,
a table driving control device for controlling the table driving device,
a gas supply device for supplying a raw material gas to the gas introduction units,
a single electromagnetic wave oscillator,
plasma generation portions each provided for corresponding discharge tubes of the gas introduction units, and
an electromagnetic wave transmission unit having an electromagnetic wave switching unit configured to switch an electromagnetic wave such that one of the plasma generation portions is irradiated with the electromagnetic wave generated by the single electromagnetic wave oscillator,
wherein the gas introduction units have fabrication characteristics different from each other.

2. The local dry etching apparatus of claim 1, wherein a distance between each of the injection ports and the workpiece is made different, whereby the gas introduction units have different fabrication characteristics.

3. The local dry etching apparatus of claim 1, wherein exhaustion units having different exhaustion conditions are located at the periphery of the injection ports, whereby the gas introduction units have different fabrication characteristics.

4. The local dry etching apparatus of claim 3, wherein
the exhaustion units each include an exhaustion duct located at the periphery of the injection port and an exhaustion mechanism connected to the exhaustion duct, and at least one of the width of the exhaustion duct in the direction perpendicular to the axis of the discharge tube and the height of the exhaustion duct in the direction identical with the axis of the discharge tube is made different for every injection port, whereby the gas introduction units have different fabrication characteristics.

5. The local dry etching apparatus of claim 3, wherein the exhaustion units each include an exhaustion duct located at the periphery of the injection port and an exhaustion mechanism connected to the exhaustion duct, and an exhaustion amount of a reaction product gas formed upon dry etching fabrication by the exhaustion mechanism is made different for every injection port, whereby the gas introduction units have different fabrication characteristics.

6. The local dry etching apparatus of claim 1, wherein the diameter or the shape of each of the injection ports is made different, whereby the gas introduction units have different fabrication characteristics.

7. The local dry etching apparatus of claim 1, wherein a distance from each of the plasma generation portions to the surface of the workpiece mounted on the workpiece table is made different, whereby the gas introduction units have different fabrication characteristics.

8. The local dry etching apparatus of claim 1, wherein different kinds of gases are supplied into the discharge tubes, whereby the gas introduction units have different fabrication characteristics.

9. The local dry etching apparatus of claim 1, wherein an inert gas and/or a non-active raw material gas supplied to the gas introduction units is supplied to the workpiece fabrication area and/or the periphery of the exhaustion ducts.

10. The local dry etching apparatus of claim 1, wherein a temperature control unit is provided for heating and/or cooling at least a portion of the gas introduction units.
